(19) United States
(12) Patent Application Publication
(10) Pub. No.: US 2025/0324758 A1
(43) Pub. Date: Oct. 16, 2025

(54) DISPLAY APPARATUS

(71) Applicant: Samsung Display Co., Ltd., Yongin-si (KR)

(72) Inventors: Kyunghwan MOON, Yongin-si (KR); Jundal KIM, Yongin-si (KR); Byunghyuk SHIN, Yongin-si (KR)

(21) Appl. No.: 19/096,672

(22) Filed: Mar. 31, 2025

(30) Foreign Application Priority Data
Apr. 16, 2024 (KR) 10-2024-0050919

(51) Int. Cl. H10D 86/40

(52) U.S. Cl. CPC H10D 86/441

(57) ABSTRACT

A display device with efficient power management includes a first substrate having a first display area, first pads disposed on the first substrate along a first edge of the first substrate, a second substrate having a second display area, second pads disposed on the second substrate along a second edge of the second substrate, a connection film having one end electrically connected to the first pads and another end electrically connected to the second pads, and a switching unit which is disposed on the first substrate along the first edge of the first substrate and which transfers an electrical signal from the first substrate to the connection film or which applies a preset electrical signal to the second display area.

This application claims priority to Korean Patent Application No. 10-2024-0050919, filed on Apr. 16, 2024, and all the benefits accruing therefrom under 35 U.S.C. § 119, the content of which in its entirety is herein incorporated by reference.

### BACKGROUND

### 1. Field

The invention relates to a display apparatus, and more particularly, to a display apparatus with efficient power management.

### 2. Description of the Related Art

In general, a display apparatus has a display area for displaying images. Such a display apparatus may be a portable electronic device where batteries of limited capacity are used, and thus, efficient power management is necessary. However, these display apparatuses have limitations in efficient power management.

### SUMMARY

One or more embodiments include a display apparatus with efficient power management.

Additional aspects will be set forth in part in the description which follows and, in part, will be apparent from the description, or may be learned by practice of the presented embodiments of the invention.

According to one or more embodiments, a display apparatus includes a first substrate having a first display area, first pads disposed on the first substrate along a first edge of the first substrate, a second substrate having a second display area, second pads disposed on the second substrate along a second edge of the second substrate, a connection film having one end electrically connected to the first pads and another end electrically connected to the second pads, and a switching unit which is disposed on the first substrate directed along the first edge of the first substrate, and transfers an electrical signal from the first substrate to the connection film or applies a preset electrical signal to the second display area.

In an embodiment, the switching unit may include a connection control unit and a signal application unit, wherein the connection control unit is configured to electrically connect the first substrate to the connection film or electrically disconnect the first substrate from the connection film, and wherein the signal application unit is configured to apply the preset electrical signal to the second display area through the connection film when the first substrate and the connection film are electrically disconnected from each other.

In an embodiment, the preset electrical signal may be a ground signal.

In an embodiment, the connection control unit may include a connection thin-film transistor having one end electrically connected to a signal line disposed on the first substrate and another end electrically connected to a connection line arranged in the connection film.

In an embodiment, the signal line may include a first data line, and the connection line may be electrically connected to a second data line which is disposed on the second substrate.

In an embodiment, the signal application unit may include a signal application thin-film transistor, the signal application thin-film transistor having one end electrically connected to a ground line and another end electrically connected to a connection line arranged in the connection film.

In an embodiment, the connection line may be electrically connected to a second data line which is disposed on the second substrate.

In an embodiment, the connection control unit may include a connection thin-film transistor having one end electrically connected to a signal line which is disposed on the first substrate and another end electrically connected to a connection line.

In an embodiment, the signal line may include a first data line, and the connection line may be electrically connected to a second data line which is disposed on the second substrate.

In an embodiment, when a turn-off signal is applied to a gate electrode of the connection thin-film transistor, a turn-on signal may be applied to a gate electrode of the signal application thin-film transistor.

In an embodiment, when a turn-on signal is applied to a gate electrode of the connection thin-film transistor, a turn-off signal may be applied to a gate electrode of the signal application thin-film transistor.

According to one or more embodiments, a display apparatus includes a first substrate having a first display area, first pads disposed on the first substrate along a first edge of the first substrate, first data lines crossing the first display area and extending in a direction to the first pads, a second substrate having a second display area, second pads disposed on the second substrate along a second edge of the second substrate, a connection film having one end electrically connected to the first pads and another end electrically connected to the second pads, connection thin-film transistors, each having one end electrically connected to a corresponding one of the first data lines and another end electrically connected to a corresponding one of the first pads, and signal application thin-film transistors, each having one end electrically connected to a ground line and another end electrically connected to a corresponding one of the first pads.

In an embodiment, gate electrodes of the connection thin-film transistors may be electrically connected to each other.

In an embodiment, the gate electrodes of the connection thin-film transistors may be integrally formed as a single body.

In an embodiment, gate electrodes of the signal application thin-film transistors may be electrically connected to each other.

In an embodiment, the gate electrodes of the signal application thin-film transistors may be integrally formed as a single body.

In an embodiment, when a turn-off signal is applied to gate electrodes of the connection thin-film transistors, a turn-on signal may be applied to gate electrodes of the signal application thin-film transistors.

In an embodiment, when a turn-on signal is applied to gate electrodes of the connection thin-film transistors, a turn-off signal may be applied to gate electrodes of the signal application thin-film transistors.

In an embodiment, the display apparatus may further include connection lines arranged in the connection film, each of the connection lines electrically connecting a corresponding one of the first pads to a corresponding one of the second pads.

In an embodiment, the display apparatus may include second data lines crossing the second display area and extending to the second pads, wherein each of the second data lines is electrically connected to a corresponding one of the second pads.

### BRIEF DESCRIPTION OF THE DRAWINGS

The above and other aspects, features, and advantages of certain embodiments will be more apparent from the following description taken in conjunction with the accompanying drawings, in which:

FIG. 1 is a perspective view schematically illustrating an appearance of a display apparatus, according to an embodiment;

FIG. 2 is a perspective view schematically illustrating an appearance of a display apparatus, according to an embodiment;

FIG. 3 is a plan view schematically illustrating a part of a display apparatus, according to an embodiment;

FIG. 4 is a plan view schematically illustrating a part of the display apparatus of FIG. 3, according to an embodiment;

FIG. 5 is a cross-sectional view schematically illustrating a cross-section of the display apparatus of FIG. 4, taken along line A-A′, according to an embodiment;

FIG. 6 is a cross-sectional view schematically illustrating a cross-section of the display apparatus of FIG. 4, taken along line B-B′, according to an embodiment;

FIG. 7 is a circuit diagram schematically illustrating a configuration that may be included in a switching unit of the display apparatus of FIG. 3, according to an embodiment; and

FIG. 8 is a circuit diagram schematically illustrating a configuration that may be included in the switching unit of the display apparatus of FIG. 3, according to an embodiment.

### DETAILED DESCRIPTION

Reference will now be made in detail to embodiments, examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the invention allows for various changes and numerous embodiments, certain embodiments will be illustrated in the drawings and described in detail in the written description. Hereinafter, effects and features of the invention and a method for accomplishing them will be described more fully with reference to the accompanying drawings, in which embodiments of the invention are shown. This invention may, however, be embodied in many different forms and should not be construed as being limited to the embodiments set forth herein.

Hereinafter, embodiments will be described with reference to the accompanying drawings, wherein like reference numerals refer to like elements throughout and a repeated description thereof is omitted.

Herein, when various elements such as layers, films, areas, plates, or the like are described to be disposed “on” other elements, it includes not only a case of being disposed “directly on” the other elements but also a case in which other elements are in between. In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

Herein, an x-axis, a y-axis, and a z-axis are not limited to the three axes in the Cartesian coordinate system, but can be interpreted in a broad sense including the same. For example, the x-axis, the y-axis, and the z-axis may be orthogonal to each other, but may also refer to directions that are not orthogonal to each other.

It will be understood that although terms such as “first” and “second” may be used herein to describe various elements, these elements should not be limited by these terms and these terms are only used to distinguish one element from another element.

In the embodiments below, it will be further understood that the terms “comprises” and/or “comprising” used herein specify the presence of stated features or elements, but do not preclude the presence or addition of one or more other features or elements.

As used herein, “A and/or B” indicates A, B, or A and B. In addition, “at least one of A and B” indicates A, B, or A and B.

In the following embodiments, when films, areas, elements, or the like are described to be connected, it includes not only a case where the films, the areas, the elements, or the like are directly connected, but also a case where the films, the areas, the elements, or the like are indirectly connected with other films, areas, or elements therebetween. For example, herein, when it is described that films, areas, elements, or the like are electrically connected, it includes not only a case where the films, areas, elements, or the like are directly electrically connected, but also a case where the films, areas, the elements, or the like are indirectly electrically connected with other films, areas, or elements therebetween.

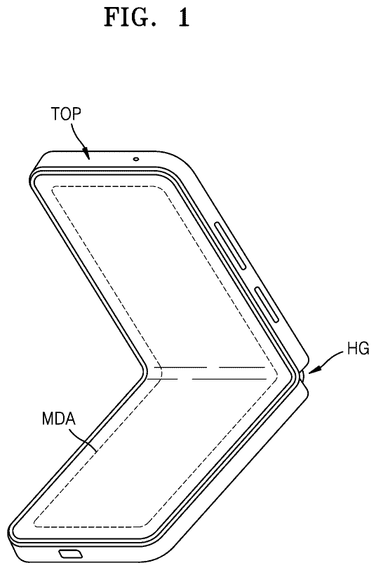

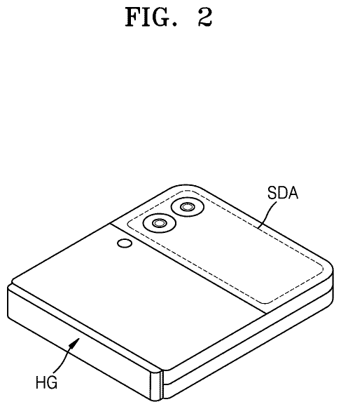

FIGS. 1 and 2 are perspective views schematically illustrating an appearance of a display apparatus, according to an embodiment.

In an embodiment and as shown in FIGS. 1 and 2, the display apparatus has a hinge HG and may be a foldable display apparatus that may be folded or unfolded in the vicinity of the hinge HG. The display apparatus may have a first display area and a second display area. For example, the first display area may be a main display area MDA and the second display area may be a sub-display area SDA. Hereinbelow, for convenience, the first display area is referred to as the main display area MDA and the second display area is referred to as the sub-display area SDA. An area of the main display area MDA may be greater than an area of the sub-display area SDA.

FIG. 1 shows the main display area MDA folded at an angle of approximately 90 degrees, and FIG. 2 shows the display apparatus fully folded. When the display apparatus is fully folded, as shown in FIG. 2, the main display area MDA may be positioned on the inside, and in that state, the user may only use the sub-display area SDA positioned on the outside. However, the display apparatus may be fully unfolded so that the main display area MDA is approximately flat. For example, this display apparatus, according to the present embodiment, may be a mobile device such as a smartphone.

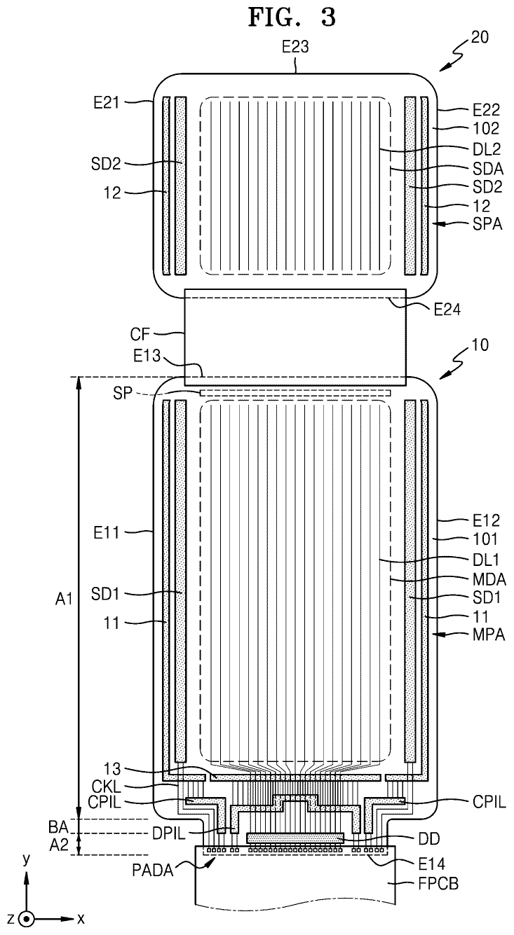

FIG. 3 is a plan view schematically illustrating a part of a display apparatus, according to an embodiment. For example, the display apparatus of FIG. 3 may be a part of the display apparatus as shown in FIGS. 1 and 2. This is described in detail below. The display apparatus, according to an embodiment may have a main display panel 10 and a sub-display panel 20.

In an embodiment, the main display panel 10 may have the main display area MDA in which a plurality of first display elements are arranged and a main peripheral area MPA positioned outside the main display area MDA. This may be understood that a first substrate 101 included in the main display panel 10 has the main display area MDA and the main peripheral area MPA.

In an embodiment, a first scan driver SD1, a driving driver DD, and various lines may be positioned in the main peripheral area MPA. This main peripheral area MPA may include a pad area PADA, and an electronic element, such as the driving driver DD, and a flexible printed circuit board FPCB may be electrically attached to the pad area PADA. In addition, a common voltage input line CPIL, a first common voltage supply line 11, a driving voltage input line DPIL, and a first driving voltage supply line 13 may also be arranged in the main peripheral area MPA. However, various lines, including a clock signal line CKL to be input to the first scan driver SD1, may also pass through the main peripheral area MPA.

In an embodiment, the driving driver DD may include an integrated circuit configured to drive the main display panel 10. This integrated circuit may be a data driving integrated circuit configured to generate data signals, but embodiments are not limited thereto. The first substrate 101 may have a first main edge E11 and a second main edge E12, which substantially extends in a first direction (y-axis direction) and which face each other, and may also have a third main edge E13 and a fourth main edge E14, which can be seen to substantially extend in a second direction (x-axis direction) crossing the first direction and to connect the first main edge E11 and the second main edge E12 to each other. The fourth main edge E14 may be positioned on an opposite side of the third main edge E13 with respect to a center of the first substrate 101. The driving driver DD may be mounted in the main peripheral area MPA to be disposed adjacent to the fourth main edge E14 of the first substrate 101. The flexible printed circuit board FPCB described above may also be understood as being electrically connected to the fourth main edge E14 of the first substrate 101. The fourth main edge E14 may be referred to as a third edge, for convenience.

For reference, FIG. 3 may be understood as a plan view illustrating the first substrate 101 during a manufacturing process, according to an embodiment. In a final display apparatus or an electronic apparatus including a display apparatus, such as a smartphone, a part of the first substrate 101 or the like may be bent to minimize an area of the main peripheral area MPA recognized by the user. For example, the main peripheral area MPA may include a bending area BA so that the bending area BA is disposed between the pad area PADA and the main display area MDA. In this case, the first substrate 101 may be bent in the bending area BA so that a first area A1 positioned on one side of the bending area BA overlaps a second area A2 positioned on the other side of the bending area BA.

In an embodiment, the first substrate 101 may be bent in the bending area BA so that at least a part of the second area A2 in which the pad area PADA is positioned overlaps the first area A1 in which the main display area MDA is positioned. In this embodiment, a bending direction is set such that the pad area PADA is positioned at the rear of the main display area MDA. Accordingly, the user may recognize the main display area MDA as occupying most of the display apparatus. The driving driver DD described above is mounted on a same surface as a display surface of the main display area MDA, but as the main display area MDA is bent in the bending area BA, the driving driver DD may be positioned in a rear direction of the main display area MDA.

In an embodiment, this first substrate 101 may include various materials having flexible or bendable properties, and may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, in another embodiment, the first substrate 101 may have a multi-layer structure, and may include two layers, which include the polymer resin, and a barrier layer therebetween, the barrier layer including an inorganic material (silicon oxide, silicon nitride, or silicon oxynitride), and various modifications may be made. Further, when the first substrate 101 is not bendable, the first substrate 101 may include glass or the like.

In an embodiment, edges of the main display area MDA may have an overall shape similar to a rectangle or square. Accordingly, the first substrate 101 may also have an overall shape similar to a rectangle or square. However, in another embodiment, the edges of the main display area MDA may have a shape such as a circle, oval, or polygon.

In an embodiment and as described above, the first substrate 101 may have the first main edge E11 and the second main edge E12, which substantially extends in the first direction (y-axis direction) and which face each other, and may also have the third main edge E13 and the fourth main edge E14, which can be seen to substantially extend in the second direction (x-axis direction) crossing the first direction and to connect the first main edge E11 and the second main edge E12 to each other. The pad area PADA may be a portion disposed adjacent to the fourth main edge E14 within the main peripheral area MPA of the first substrate 101. However, in another embodiment, the first substrate 101 may have a bending portion disposed between the first main edge E11 and the fourth main edge E14 and between the second main edge E12 and the fourth main edge E14, so that bending of the first substrate 101 or the like in the bending area BA may be facilitated. Accordingly, as shown in FIG. 3, a width of the first substrate 101 in the second direction (x-axis direction) in the second area A2 may be less than a width of the first substrate 101 in the second direction (x-axis direction) in the first area A1.

In an embodiment, hereinbelow, an organic light-emitting display is described as an example of a display apparatus, but the display apparatus is not limited thereto. In another embodiment, the display apparatus may be an inorganic light-emitting display (or, inorganic electroluminescent (EL) display apparatus) or a display apparatus such as a quantum dot light-emitting display. For example, an emission layer of a display element included in the display apparatus may include an organic material or an inorganic material. In addition, in another embodiment, the display apparatus may have an emission layer and quantum dots positioned on a path of light emitted from the emission layer.

In an embodiment, a plurality of pixels may be positioned in the main display area MDA, where each of the pixels refers to a sub-pixel and may include a first display element, such as an organic light-emitting diode (OLED), and a pixel circuit electrically connected to the first display element. For example, in an embodiment, the pixel may emit red, green, blue, or white light. The pixel may be electrically connected to outer circuits arranged in the main peripheral area MPA. The first scan driver SD1, the first common voltage supply line 11, and the first driving voltage supply line 13 may be arranged in the main peripheral area MPA.

In an embodiment, the first scan driver SD1 may extend along the first main edge E11 of the first substrate 101. This first scan driver SD1 may be configured to provide a scan signal to the pixels through a scan line (not shown), which extends in the second direction (x-axis direction) into the main display area MDA. However, in an embodiment, the first substrate 101 may be positioned along the second main edge E12 of the first substrate 101. In this embodiment, some of pixels arranged in the main display area MDA may be electrically connected to the first scan driver SD1 disposed near the first main edge E11, and remaining pixels may be electrically connected to the first scan driver SD1 disposed near the second main edge E12. In another embodiment, an emission control driver other than the first scan driver SD1 may be positioned near the second main edge E12 of the first substrate 101 to provide an emission control signal or the like to a pixel within the main display area MDA through an emission control line (not shown), which is substantially directed parallel to the scan line.

In an embodiment, a plurality of main pads may be positioned in the pad area PADA of the main display panel 10. The plurality of main pads may be exposed without being covered by an insulating layer, and electrically connected to the flexible printed circuit board FPCB. In other words, pads of the flexible printed circuit board FPCB may be electrically connected to the plurality of main pads of the main display panel 10.

In an embodiment, the flexible printed circuit board FPCB may transfer a signal or power of a control unit to the main display panel 10. A control signal generated by the control unit may be transferred to the driving driver DD, the first scan driver SD1, or the like through the flexible printed circuit board FPCB. In addition, the control unit may provide a common voltage ELVSS to the first common voltage supply line 11 through the common voltage input line CPIL and provide the common voltage ELVSS to common electrodes of organic light-emitting elements positioned in the main display area MDA. In addition, the control unit may provide a driving voltage ELVDD to the first driving voltage supply line 13 through a driving voltage input line DPIL and may provide the driving voltage ELVDD to pixel circuits positioned in the main display area MDA through first driving voltage lines (not shown), which extend in the first direction (y-axis direction) into the main display area MDA from the first driving voltage supply line 13. The first driving voltage lines may be directed substantially parallel to first data lines DL1. For reference, as shown in FIG. 3, the first common voltage supply line 11 may have a shape substantially extending in the first direction (y-axis direction) along each of the first main edge E11 and the third main edge E13. However, unlike the above, the first common voltage supply line 11 may have a loop shape with one open side directed toward the fourth main edge E14 and may have a shape extending along the first main edge E11, the third main edge E13, and the second main edge E12.

In an embodiment, the control unit may generate a data signal, and the generated data signal may be transferred to a pixel within the main display area MDA through the driving driver DD and the first data line DL1, which extends in the first direction (y-axis direction) and which crosses the main display area MDA. In addition, in the drawings, the clock signal line CKL receives a clock signal through a main pad and transfers the received clock signal to the first scan driver SD1. However, in another embodiment, the clock signal line CKL may receive a clock signal from the driving driver DD and transfer the received clock signal to the first scan driver SD1.

In an embodiment, similar to the main display panel 10, the sub-display panel 20 may have the sub-display area SDA, in which a plurality of pixels are positioned, and a sub-peripheral area SPA positioned outside the sub-display area SDA. This may be understood that a second substrate 102 included in the sub-display panel 20 has the sub-display area SDA and the sub-peripheral area SPA. A second scan driver SD2 and various lines may be positioned in the sub-peripheral area SPA. Although not shown in FIG. 3, in another embodiment, a second driving voltage supply line may be arranged in the sub-peripheral area SPA, similar to the first driving voltage supply line 13.

In an embodiment, the second substrate 102 may include various materials having flexible or bendable properties, and may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the second substrate 102 may have a multi-layer structure, and may include two layers, which include the polymer resin, and a barrier layer therebetween, the barrier layer including an inorganic material (silicon oxide, silicon nitride, or silicon oxynitride), and various modifications may be made. Further, when the second substrate 102 is not flexible, the second substrate 102 may include glass or the like.

In an embodiment, edges of the sub-display area SDA may have an overall shape similar to a rectangle or square. Accordingly, the second substrate 102 may also have an overall shape similar to a rectangle or square. However, in another embodiment, the edges of the sub-display area SDA may have a shape such as a circle, oval, or polygon. In addition, when components such as a camera or an illumination sensor are positioned within the sub-display area SDA, an opening may be positioned within the sub-display area SDA so that those components may be positioned therein. For reference, FIG. 2 shows that a camera or the like is positioned within the sub-display area SDA.

In an embodiment, the second substrate 102 may have a first sub-edge E21 and a second sub-edge E22, which substantially extend in the first direction (y-axis direction) and which face each other, and may also have a third sub-edge E23 and a fourth sub-edge E24, which can be seen to substantially extend in the second direction (x-axis direction) and to connect the first sub-edge E21 and the second sub-edge E22 to each other. The fourth sub-edge E24 of the second substrate 102 may be positioned adjacent to the third main edge E13 of the first substrate 101.

In an embodiment, a plurality of pixels may be positioned in the sub-display area SDA, where each of the pixels refers to a sub-pixel and may include a second display element, such as an OLED, and a pixel circuit electrically connected to the second display element. For example, in an embodiment, the pixel may emit red, green, blue, or white light. The pixel may be electrically connected to outer circuits arranged in the sub-peripheral area SPA. The second scan driver SD2, a second common voltage supply line 12, or the like may be arranged in the sub-peripheral area SPA, and if necessary, the second driving voltage supply line or the like may be arranged in the sub-peripheral area SPA.

In an embodiment, the second scan driver SD2 may extend along the first sub-edge E21 of the second substrate 102, where the second scan driver SD2 may be configured to provide a scan signal to the pixels through a scan line (not shown), which extends in the second direction (x-axis direction) into the sub-display area SDA. However, in another embodiment, the second scan driver SD2 may be positioned along the second sub-edge E22 of the second substrate 102. In this case, some of pixels arranged in the sub-display area SDA may be electrically connected to the second scan driver SD2 near the first sub-edge E21, and the remaining pixels may be electrically connected to the second scan driver SD2 near the second sub-edge E22. In another embodiment, an emission control driver other than the second scan driver SD2 may be positioned near the second sub-edge E22 of the second substrate 102 to provide an emission control signal or the like to a pixel within the sub-display area SDA through an emission control line (not shown), which is directed substantially parallel to the scan line.

Unlike the driving driver DD mounted on the main display panel 10, in an embodiment, the driving driver DD may not be mounted on a second display panel 20. Instead, an electrical signal from the driving driver DD mounted on the main display panel 10 is transferred to the second display panel 20 so that the electrical signal may be transferred to the pixels within the sub-display area SDA of the second display panel 20 through a second data line DL2 extending in the first direction (y-axis direction) and crossing the sub-display area SDA. To this end, as shown in FIG. 3, a connection film CF may electrically connect the main display panel 10 and the second display panel 20 to each other. This is described in detail below.

For reference, FIG. 3 may be understood as a plan view illustrating the first substrate 101 and the second substrate 102 during a manufacturing process, according to an embodiment. In a final display apparatus or an electronic apparatus including a display apparatus, such as a smartphone, in order to create an electronic apparatus as described above with reference to FIGS. 1 and 2, the connection film CF is bent so that a rear surface of the second display panel 20 and a rear surface of the main display panel 10 may face each other. In other words, the rear surface of the second substrate 102 may be positioned on a rear surface of the first substrate 101. A bending portion of the connection film CF may be at a portion indicated as a top TOP of the display apparatus in FIG. 1. In this case, at least a part of the flexible printed circuit board FPCB attached to the pad area PADA of the main display panel 10, or at least a part of a circuit board or the like electrically connected to such flexible printed circuit board FPCB may be positioned between the main display panel 10 and the second display panel 20.

In an embodiment, the first common voltage supply line 11 of the main display panel 10 may be electrically connected to the second common voltage supply line 12 of the second display panel 20 through the connection film CF, and may provide the common voltage ELVSS to a common electrode of an organic light-emitting element positioned in the sub-display area SDA. As shown in FIG. 3, the second common voltage supply line 12 may have a shape substantially extending in the first direction (y-axis direction) along each of the first sub-edge E21 and the third sub-edge E23. However, unlike the above, in an embodiment, the second common voltage supply line 12 may have a loop shape with one open side toward the fourth sub-edge E24 and may have a shape extending along the first sub-edge E21, the third sub-edge E23, and the second sub-edge E22.

Further, in an embodiment, first driving voltage lines, which extend in the first direction (y-axis direction) into the main display area MDA from the first driving voltage supply line 13, may also be electrically connected to second driving voltage supply lines of the second display panel 20 through the connection film CF. Accordingly, the driving voltage ELVDD may be provided to pixel circuits positioned within the sub-display area SDA through second driving voltage lines (not shown) extending in the first direction (y-axis direction) into the sub-display area SDA from the second driving voltage supply line. The second driving voltage lines may be directed to be substantially parallel to the second data lines DL2.

In an embodiment, the first scan driver SD1 of the main display panel 10 may also be electrically connected to the second scan driver SD2 of the second display panel 20 through the connection film CF. This may be understood that a clock signal or the like applied to the first scan driver SD1 is applied to the second scan driver SD2 of the second display panel 20 through the connection film CF.

For reference, the common voltage ELVSS, the driving voltage ELVDD, and/or the clock signal may be an electrical signal transferred from the flexible printed circuit board FPCB to the main display panel 10. In another embodiment, an electrical signal may be applied to the driving driver DD mounted on the main display panel 10 through the flexible printed circuit board FPCB, and by using the electrical signal, a data signal or the like generated by the driving driver DD may be transferred to second display elements of the sub-display panel 20 through the connection film CF. Therefore, the connection film CF may be understood as ultimately transferring electrical signals from the flexible printed circuit board FPCB to the second display elements of the sub-display panel 20.

Meanwhile, the display apparatus, according to an embodiment, may have a switching unit SP, where the switching unit SP may be disposed on the first substrate 101 along the third main edge E13 of the first substrate 101 of the main display panel 10. This switching unit SP may allow an electrical signal to be transferred from the first substrate 101 to the connection film CF, or may allow a preset electrical signal to be applied to the sub-display area SDA. In other words, the switching unit SP may transfer the electrical signal from the first substrate 101 to the connection film CF, or may apply the preset electrical signal to the sub-display area SDA. This is described in detail below.

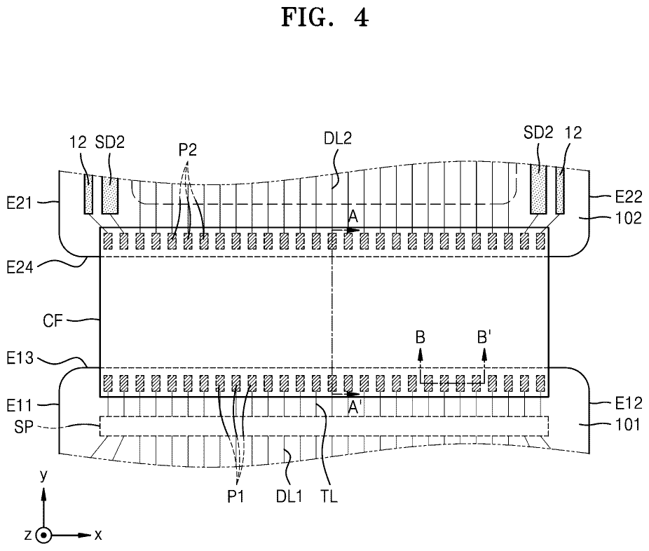

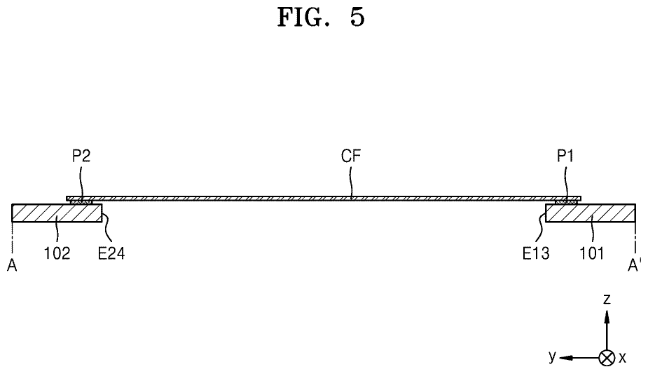

FIG. 4 is a plan view schematically illustrating a part of the display apparatus of FIG. 3, according to an embodiment, and FIG. 5 is a cross-sectional view schematically illustrating a cross-section of the display apparatus of FIG. 4, taken along line A-A′, according to an embodiment.

In an embodiment, first pads P1 may be disposed on the first substrate 101. Specifically, near the third main edge E13, which is an edge of the first substrate 101 in the direction toward the second substrate 102, the first pads P1 may be arranged along the third main edge E13. In other words, the first pads P1 may be arranged in the second direction (x-axis direction) near the third main edge E13. For convenience, the third main edge E13 may be referred to as a first edge. The first pads P1 may be exposed without being covered by an insulating layer, and may be electrically connected to the connection film CF as described below. In FIG. 3, the first pads P1 are not shown and are omitted for convenience of illustration.

In an embodiment, second pads P2 may be disposed on the second substrate 102. Specifically, near the fourth sub-edge E24, which is an edge of the second substrate 102 in a direction toward the first substrate 101, the second pads P2 may be arranged along the fourth sub-edge E24. In other words, the second pads P2 may be arranged in the second direction (x-axis direction) near the fourth sub-edge E24. For convenience, the fourth sub-edge E24 may be referred to as a second edge. The second pads P2 may be exposed without being covered by an insulating layer, and may be electrically connected to the connection film CF. In FIG. 3, the second pads P2 are not shown and are omitted for convenience of illustration.

In an embodiment, the connection film CF may have one end (in a −y direction) electrically connected to the first pads P1 on the first substrate 101 and the other end (in a +y direction) electrically connected to the second pads P2 on the second substrate 102. The connection film CF may include connection lines, where each of these connection lines may electrically connect a corresponding one of the first pads P1 on the first substrate 101 to a corresponding one of the second pads P2 on the second substrate 102. In other words, one connection line of the connection film CF may electrically connect any one of the first pads P1 on the first substrate 101 to a corresponding pad from among the second pads P2 on the second substrate 102.

In an embodiment and as described above, the driving driver DD including an integrated circuit configured to drive the main display panel 10 may be mounted on the first substrate 101. This integrated circuit may be a data driving integrated circuit configured to generate data signals, where a data signal from the driving driver DD may be transferred to the pixels within the main display panel 10 and may be transferred to the first data line DL1, where the main display panel 10 includes the first substrate 101.

In an embodiment, unlike the driving driver DD mounted on the main display panel 10, the driving driver DD may not be mounted on the sub-display panel 20. Accordingly, a device for transferring a data signal to the pixels within the sub-display area SDA of the sub-display panel 20 is required. In the display apparatus, according to an embodiment, the connection film CF may serve to transfer an electrical signal from the driving driver DD to the second display elements within the sub-display area SDA.

Specifically, in an embodiment, the driving driver DD mounted on the main display panel 10 may even generate data signals to be transferred to the pixels within the sub-display area SDA of the sub-display panel 20. This data signal may be transferred to the second data line DL2 of the sub-display panel 20 through at least some of the first data lines DL1 of the main display panel 10, at least some of the first pads P1, at least some of the connection lines of the connection film CF, and at least some of the second pads P2. In other words, each of the second data line DL2 may be electrically connected to a corresponding pad from among the second pads P2. When a number of the first data lines DL1 of the main display panel 10 is equal to a number of the second data lines DL2 of the sub-display panel 20, the first data lines DL1 and the second data lines DL2 may be electrically connected one-to-one to each other by the connection lines of the connection film CF.

In an embodiment and as described above, the second scan driver SD2 extending along the first sub-edge E21 of the second substrate 102 may provide a scan signal to pixels through a scan line (not shown) extending in the second direction (x-axis direction) into the sub-display area SDA. A clock signal or the like for the second scan driver SD2 to generate a scan signal may be transferred to the second scan driver SD2 through at least some of the first pads P1 on the first substrate 101, the connection lines of the connection film CF, and at least some of the second pads P2 on the second substrate 102.

In an embodiment, the common voltage ELVSS to be applied to the common electrode of the organic light-emitting elements positioned in the sub-display area SDA may be applied through the second common voltage supply line 12 of the sub-display panel 20. Thus, the second common voltage supply line 12 of the sub-display panel 20 is electrically connected to the first common voltage supply line 11 of the main display panel 10. The first common voltage supply line 11 of the main display panel 10 may be electrically connected to the second common voltage supply line 12 of the sub-display panel 20 through at least some of the first pads P1 on the first substrate 101, the connection lines of the connection film CF, and at least some of the second pads P2 on the second substrate 102.

In an embodiment, the driving voltage ELVDD to be applied to the organic light-emitting elements positioned in the sub-display area SDA may be applied through the second driving voltage lines extending into the sub-display area SDA and being directed substantially parallel to the second data lines DL2. Thus, the second driving voltage lines of the sub-display panel 20 are electrically connected to the first driving voltage lines of the main display panel 10. The first driving voltage lines of the main display panel 10 may be electrically connected to the second driving voltage lines of the sub-display panel 20 through at least some of the first pads P1 on the first substrate 101, the connection lines of the connection film CF, and at least some of the second pads P2 on the second substrate 102.

In an embodiment and as described above, the first driving voltage supply line 13 may be positioned in the main display panel 10, and the first driving voltage supply lines may extend in the first direction (y-axis direction) from the first driving voltage supply line 13 so that the first driving voltage lines may cross the main display area MDA. Similarly, the second driving voltage supply line (not shown) of the sub-display panel 20 may be positioned near the fourth sub-edge E24, and the second driving voltage lines may extend in the first direction (y-axis direction) from the second driving voltage supply lines, so that the second driving voltage lines may cross the sub-display area SDA. In this embodiment, the first driving voltage lines of the main display panel 10 may be electrically connected to the second driving voltage supply line of the sub-display panel 20 through at least some of the first pads P1 on the first substrate 101, the connection lines of the connection film CF, and at least some of the second pads P2 on the second substrate 102. In this embodiment, the second driving voltage supply line may be disposed on a layer different from a layer on which the second data lines DL2 are disposed, so that the second driving voltage supply line and the second data lines DL2 are electrically insulated from each other.

For convenience, in FIG. 4, connection lines electrically connected to the first pads P1 on the first substrate 101, and connection lines electrically connected to the second pads P2 are not shown. For example, at least some of the first data lines DL1 on the first substrate 101 may be electrically connected to some of the first pads P1 on the first substrate 101 through the connection lines, and the second data lines DL2 on the second substrate 102 may be electrically connected to some of the second pads P2 through the connection lines.

As described above, the display apparatus, according to an embodiment, does not require a separate driving driver or circuit board for operating the sub-display panel 20, thereby reducing manufacturing costs.

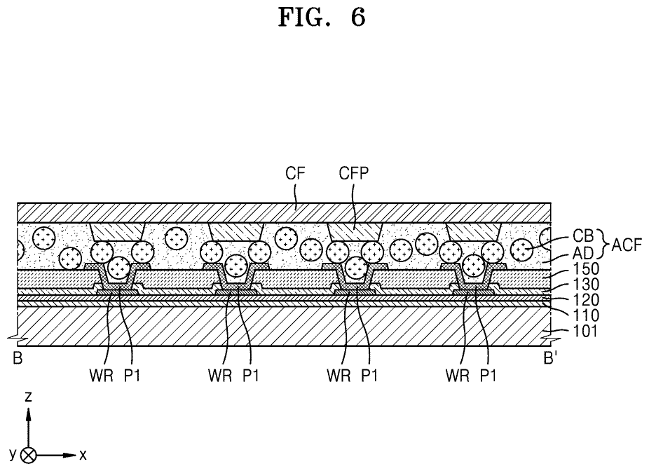

FIG. 6 is a cross-sectional view schematically illustrating a cross-section of the display apparatus of FIG. 4, taken along line B-B′, according to an embodiment. Not only the first pads P1 are disposed on the first substrate 101, but also a buffer layer 110, a first gate insulating film 120, a second gate insulating film 130, and an interlayer insulating film 150 may be disposed on the first substrate 101, as shown in FIG. 6.

In an embodiment, the buffer layer 110 may be disposed between a semiconductor layer of a thin-film transistor, included in the pixel circuit positioned in the main display area MDA, and the first substrate 101 and may extend to the main peripheral area MPA. The buffer layer 110 may include an inorganic material such as silicon oxide, silicon nitride, and/or silicon oxynitride. This buffer layer 110 may increase smoothness of an upper surface of the first substrate 101 or prevent or minimize permeation of impurities into the semiconductor layer of the thin-film transistor from the first substrate 101 or the like.

In an embodiment, the first gate insulating film 120 may be disposed between the semiconductor layer and a gate electrode thereon, and may extend to the main peripheral area MPA, similar to the buffer layer 110. The first gate insulating film 120 may include an inorganic material such as silicon oxide, silicon nitride, and/or silicon oxynitride.

In an embodiment, the second gate insulating film 130 may be disposed between the gate electrode and a first conductive layer thereon, and the interlayer insulating film 150 may be disposed between the first conductive layer and a second conductive layer thereon. Similar to the first gate insulating film 120, the second gate insulating film 130 and the interlayer insulating film 150 may extend to the main peripheral area MPA. The second gate insulating film 130 and the interlayer insulating film 150 may include an inorganic material such as silicon oxide, silicon nitride, and/or silicon oxynitride.

However, this is only an example, and in other embodiments, various other insulating layers may be disposed on the first substrate 101, and conductive layers that serve as lines or connection electrodes may be positioned between those insulating layers. In an embodiment and referring to FIG. 6, as an example, lines WR may be positioned between the first gate insulating film 120 and the second gate insulating film 130, and the first pads P1 disposed on the interlayer insulating film 150 are in contact with a corresponding line from among the lines WR.

For example, in an embodiment, the line WR between the first gate insulating film 120 and the second gate insulating film 130 may be simultaneously formed when a gate electrode of a thin-film transistor positioned in the main display area MDA is formed and may include a same material. However, in an embodiment, an intermediate line may be positioned between the second gate insulating film 130 and the interlayer insulating film 150, and this intermediate line may come in contact with the line WR. In this case, for example, the intermediate layer may be simultaneously formed when the first conductive layer within the main display area MDA is formed, and may include a same material.

In FIGS. 4 and 5, for convenience, the lines WR are not shown. For example, at least some of these lines WR may be electrically connected to a corresponding first data line from among the first data lines DL1 or may be integrally formed as a single body with the corresponding one of the first data lines DL1.

In an embodiment, the first pads P1 may be simultaneously formed when a conductive layer positioned on the interlayer insulating film 150 within the main display area MDA is formed, and may include a same material. In addition, the first pads P1 may have a multi-layer structure. For example, the first pad P1 may have a multi-layer structure of titanium/aluminum/titanium. In another embodiment, the first pad P1 may have a multi-layer structure of titanium/aluminum/titanium/indium titanium oxide (ITO).

In an embodiment and as shown in FIG. 6, connection film pads CFP of the connection film CF may be electrically connected to a corresponding one of the first pads P1. To this end, an isotropic conductive film ACF may be disposed between the connection film pads CFP and the first pads P1. The isotropic conductive film ACF may include an adhesive member AD and conductive balls CB. Because the adhesive member AD has an adhesive force, a part of the connection film CF and the first substrate 101 may be bonded to each other. In this case, the conductive ball CB may be disposed between the connection film pads CFP and the first pads P1 so that each of the connection film pads CFP is electrically connected to a corresponding one of the first pads P1.

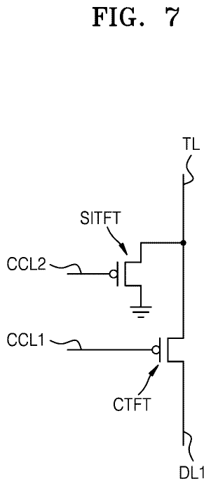

FIG. 7 is a circuit diagram schematically illustrating a configuration that may be included in the switching unit SP of the display apparatus of FIG. 3, according to an embodiment. The switching unit SP may include a connection control unit and a signal application unit. In FIG. 7, the connection control unit includes a connection thin-film transistor CTFT and the signal application unit includes a signal application thin-film transistor SITFT.

In an embodiment, the connection control unit including the connection thin-film transistor CTFT may electrically connect the first substrate 101 to the connection film CF or electrically disconnect the first substrate 101 from the connection film CF. To this end, as shown in FIG. 7, the connection thin-film transistor CTFT may have one end electrically connected to a signal line disposed on the first substrate 101 and the other end electrically connected to a connection line arranged in the connection film CF.

In an embodiment and as shown in FIG. 7, one end of the connection thin-film transistor CTFT is electrically connected to the first data line DL1, which is a signal line disposed on the first substrate 101. In addition, in FIG. 7, the other end of the connection thin-film transistor CTFT is electrically connected to a transfer line TL which is disposed on the first substrate 101 and which is electrically connected to the first pad P1, so that the other end of the connection thin-film transistor CTFT is electrically connected to the connection line arranged in the connection film CF and thus electrically connected to the second data line DL2, which is a signal line disposed on the second substrate 102.

A gate electrode of this connection thin-film transistor CTFT may be electrically connected to a first connection control line CCL1. Accordingly, when a turn-on signal is applied to the gate electrode of the connection thin-film transistor CTFT through the first connection control line CCL1, the connection thin-film transistor CTFT may electrically connect the first data line DL1 to the second data line DL2, and when a turn-off signal is applied to the gate electrode of the connection thin-film transistor CTFT through the first connection control line CCL1, the connection thin-film transistor CTFT may electrically disconnect the first data line DL1 from the second data line DL2.

As described above, the display apparatus, according to an embodiment, may have the main display area MDA and the sub-display area SDA. As shown in FIG. 1, when the user uses the main display area MDA, the user may not use the sub-display area SDA. Accordingly, in this case, a turn-off signal is applied to the gate electrode of the connection thin-film transistor CTFT through the first connection control line CCL1 and an image may not be displayed in the sub-display area SDA. Through this, power usage of the display apparatus may be efficiently managed.

In an embodiment, when the connection control unit including the connection thin-film transistor CTFT electrically disconnects the first substrate 101 from the connection film CF, the signal application unit including the signal application thin-film transistor SITFT may apply a preset electrical signal to the sub-display area SDA through the connection film CF. Here, the preset electrical signal may be a ground signal. To this end, as shown in FIG. 7, the signal application thin-film transistor SITFT may have one end electrically connected to a ground line and the other end electrically connected to a connection line arranged in the connection film CF.

In FIG. 7, one end of the signal application thin-film transistor SITFT is electrically connected to the ground line. In addition, in FIG. 7, the other end of the signal application thin-film transistor SITFT is electrically connected to the transfer line TL electrically connected to the first pad P1, so that the other end of the signal application thin-film transistor SITFT is electrically connected to the connection line arranged in the connection film CF and thus electrically connected to the second data line DL2, which is a signal line disposed on the second substrate 102.

A gate electrode of this signal application thin-film transistor SITFT may be electrically connected to a second connection control line CCL2. Accordingly, when a turn-on signal is applied to the gate electrode of the signal application thin-film transistor SITFT through the second connection control line CCL2, the signal application thin-film transistor SITFT may be configured to apply a ground signal to the second data line DL2, and when a turn-off signal is applied to the gate electrode of the signal application thin-film transistor SITFT through the second connection control line CCL2, the signal application thin-film transistor SITFT may electrically disconnect the ground line from the second data line DL2. For reference, that the ground signal is applied to the second data line DL2 may denote that the second data line DL2 is electrically connected to the ground line.

In an embodiment and as described above, the display apparatus may have the main display area MDA and the sub-display area SDA. As shown in FIG. 1, when the user uses the main display area MDA, the user may not use the sub-display area SDA. Accordingly, in this embodiment, a turn-off signal is applied to the gate electrode of the connection thin-film transistor CTFT through the first connection control line CCL1, an image may not be displayed in the sub-display area SDA. Furthermore, in this embodiment, a turn-on signal is applied to the gate electrode of the signal application thin-film transistor SITFT through the second connection control line CCL2 so that a ground signal is applied to the second data line DL2 of the sub-display area SDA, thereby preventing unwanted power consumption in the sub-display area SDA and efficiently managing power consumption of the display apparatus.

In an embodiment and as shown in FIG. 1, when the user uses the sub-display area SDA by folding the display apparatus, the user may use only the sub-display area SDA. In this case, because an image or the like must be displayed in the sub-display area SDA, a turn-on signal may be applied to the gate electrode of the connection thin-film transistor CTFT through the first connection control line CCL1 so that the data signal from the driving driver DD is transferred to the second data lines DL2 through the first data lines DL1, the transfer lines TL, the first pads P1, the connection lines of the connection film CF, and the second pads P2, or the like. In this case, a turn-off signal may be applied to the gate electrode of the signal application thin-film transistor SITFT. For reference, in this case, the main display area MDA is not used, and thus, the data signal from the driving driver DD may include a signal (e.g., a black luminance signal) that prevents light from being emitted from the main display area MDA.

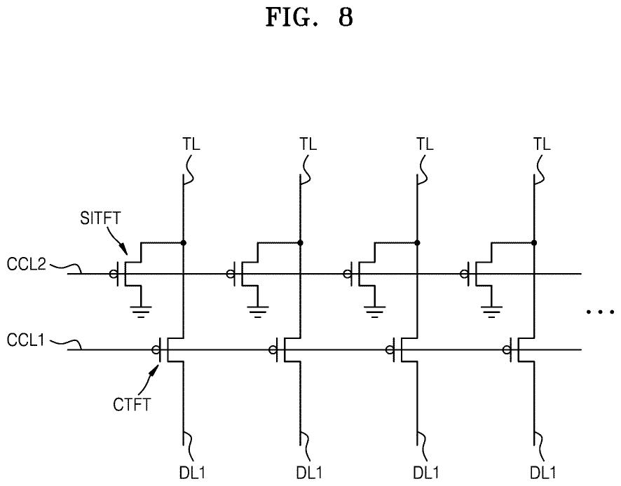

FIG. 8 is a circuit diagram schematically illustrating a configuration that may be included in the switching unit of the display apparatus of FIG. 3, according to an embodiment. As described above, a plurality of first data lines DL1 may be disposed on the first substrate 101. Accordingly, as shown in FIG. 8, a plurality of connection thin-film transistors CTFT and a plurality of signal application thin-film transistors SITFT may be arranged.

In an embodiment, one connection thin-film transistor CTFT and one signal application thin-film transistor SITFT may be electrically connected to each of the first data lines DL1. In other words, one end of the connection thin-film transistor CTFT may be electrically connected to a corresponding one of the first data lines DL1, which are signal lines disposed on the first substrate 101. In addition, the other end of the connection thin-film transistor CTFT is electrically connected to the transfer line TL which is electrically connected to a corresponding one of the first pads P1, so that the other end of the connection thin-film transistor CTFT is electrically connected to a corresponding one of the connection lines arranged in the connection film CF and is thus electrically connected to a corresponding one of the second data lines DL2, which are signal lines disposed on the second substrate 102.

Gate electrodes of this connection thin-film transistors CTFT may be electrically connected to a first connection control line CCL1. Accordingly, when a turn-on signal is applied to the gate electrodes of the connection thin-film transistors CTFT through the first connection control line CCL1, the connection thin-film transistors CTFT may electrically connect the first data line DL1 and the second data line DL2 corresponding to each other, and when a turn-off signal is applied to the gate electrodes of the connection thin-film transistors CTFT through the first connection control line CCL1, the connection thin-film transistors CTFT may electrically disconnect the first data lines DL1 from the second data lines DL2.

In an embodiment and as described above, the display apparatus may have the main display area MDA and the sub-display area SDA. As shown in FIG. 1, when the user uses the main display area MDA, the user may not use the sub-display area SDA. Accordingly, in this case, a turn-off signal is applied to the gate electrodes of the connection thin-film transistors CTFT through the first connection control line CCL1, an image may not be displayed in the sub-display area SDA. Through this, power usage of the display apparatus may be efficiently managed.

For reference, as shown in FIG. 8, the gate electrodes of the connection thin-film transistors CTFT may be electrically connected to each other. Furthermore, if necessary, the gate electrodes of the connection thin-film transistors CTFT may be integrally formed as a single body. In this case, the gate electrodes of the connection thin-film transistors CTFT may have a conductive shape which extends in the second direction (x-axis direction) along the third main edge E13 of the first substrate 101.

In an embodiment and as described above, one connection thin-film transistor CTFT and one signal application thin-film transistor SITFT may be electrically connected to each of the first data lines DL1. Accordingly, one end of the signal application thin-film transistor SITFT may be electrically connected to the ground line. The other end of the signal application thin-film transistor SITFT is electrically connected to the transfer line TL electrically connected to a corresponding one of the first pads P1, so that the other end of the signal application thin-film transistor SITFT is electrically connected to a corresponding one of the connection lines arranged in the connection film CF and thus electrically connected to a corresponding one of the second data lines DL2, which are signal lines disposed on the second substrate 102.

Gate electrodes of this signal application thin-film transistors SITFT may be electrically connected to a second connection control line CCL2. Accordingly, when a turn-on signal is applied to the gate electrodes of the signal application thin-film transistors SITFT through the second connection control line CCL2, the signal application thin-film transistors SITFT may be configured to apply a ground signal to the second data lines DL2, and when a turn-off signal is applied to the gate electrodes of the signal application thin-film transistors SITFT through the second connection control line CCL2, the signal application thin-film transistors SITFT may electrically disconnect the ground line from the second data lines DL2. For reference, that the ground signal is applied to the second data lines DL2 and may denote that the second data lines DL2 are electrically connected to the ground line.

In an embodiment and as described above, the display apparatus may have the main display area MDA and the sub-display area SDA. As shown in FIG. 1, when the user uses the main display area MDA, the user may not use the sub-display area SDA. Accordingly, in this case, a turn-off signal is applied to the gate electrodes of the connection thin-film transistors CTFT through the first connection control line CCL1, an image may not be displayed in the sub-display area SDA. Furthermore, in this case, a turn-on signal is applied to the gate electrodes of the signal application thin-film transistors SITFT through the second connection control line CCL2 so that a ground signal is applied to the second data lines DL2 of the sub-display area SDA, thereby preventing unwanted power consumption in the sub-display area SDA and efficiently managing power consumption of the display apparatus.

In an embodiment and as shown in FIG. 8, the gate electrodes of the signal application thin-film transistor SITFT may be electrically connected to each other. Furthermore, in an embodiment, the gate electrodes of the signal application thin-film transistor SITFT may be integrally formed as a single body. In this case, the gate electrodes of the signal application thin-film transistor SITFT may have a conductive shape extending in the second direction (x-axis direction) along the third main edge E13 of the first substrate 101.

In an embodiment and as shown in FIG. 1, when the user uses the sub-display area SDA by folding the display apparatus, the user may use only the sub-display area SDA. In this case, because an image or the like must be displayed in the sub-display area SDA, a turn-on signal may be applied to the gate electrodes of the connection thin-film transistors CTFT through the first connection control line CCL1 so that the data signal from the driving driver DD is transferred to the second data lines DL2 through the first data lines DL1, the transfer lines TL, the first pads P1, the connection lines of the connection film CF, and the second pads P2, or the like. Meanwhile, in this case, a turn-off signal may be applied to the gate electrodes of the signal application thin-film transistors SITFT. For reference, in this case, the main display area MDA is not used, and thus, the data signal from the driving driver DD may include a signal (e.g., a black luminance signal) that prevents light from being emitted from the main display area MDA.

Although, in an embodiment, it is described above that the driving driver DD and the switching unit SP are positioned in the main display panel 10, the invention is not limited thereto. For example, the driving driver DD and the switching unit SP may be positioned in the sub-display panel 20, and the flexible printed circuit board FPCB may be electrically connected to the sub-display panel 20, so that the switching unit SP may allow a data signal or ground signal to be applied to the main display area MDA of the main display panel 10. In other words, it may be considered that the description of the main display panel 10 in the description provided above with reference to the drawings may be considered as a description of the sub-display panel, and the description of the sub-display panel 20 in the description provided above with reference to the main display panel.

According to one or more embodiments configured as described above, display apparatuses with efficient power management may be implemented. However, the scope of the invention is not limited by these effects.

It should be understood that embodiments described herein should be considered in a descriptive sense only and not for purposes of limitation. Descriptions of features or aspects of each embodiment should be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display apparatus comprising:
a first substrate having a first display area;
first pads disposed on the first substrate along a first edge of the first substrate;
a second substrate having a second display area;
second pads disposed on the second substrate along a second edge of the second substrate;
a connection film having one end electrically connected to the first pads and another end electrically connected to the second pads; and
a switching unit which is disposed on the first substrate along the first edge of the first substrate and which transfers an electrical signal from the first substrate to the connection film or which applies a preset electrical signal to the second display area.

2. The display apparatus of claim 1, wherein the switching unit comprises a connection control unit and a signal application unit, wherein the connection control unit is configured to electrically connect the first substrate to the connection film or electrically disconnect the first substrate from the connection film, and wherein the signal application unit is configured to apply the preset electrical signal to the second display area through the connection film when the first substrate and the connection film are electrically disconnected from each other.

3. The display apparatus of claim 2, wherein the preset electrical signal comprises a ground signal.

4. The display apparatus of claim 2, wherein the connection control unit comprises a connection thin-film transistor having one end electrically connected to a signal line disposed on the first substrate and another end electrically connected to a connection line arranged in the connection film.

5. The display apparatus of claim 4, wherein the signal line comprises a first data line, and wherein the connection line is electrically connected to a second data line disposed on the second substrate.

6. The display apparatus of claim 2, wherein the signal application unit comprises a signal application thin-film transistor having one end electrically connected to a ground line and another end electrically connected to a connection line that is arranged in the connection film.

7. The display apparatus of claim 6, wherein the connection line is electrically connected to a second data line disposed on the second substrate.

8. The display apparatus of claim 6, wherein the connection control unit comprises a connection thin-film transistor having one end electrically connected to a signal line which is disposed on the first substrate and another end electrically connected to the connection line.

9. The display apparatus of claim 8, wherein the signal line comprises a first data line, and wherein the connection line is electrically connected to a second data line disposed on the second substrate.

10. The display apparatus of claim 8, wherein when a turn-off signal is applied to a gate electrode of the connection thin-film transistor, a turn-on signal is applied to a gate electrode of the signal application thin-film transistor.

11. The display apparatus of claim 8, wherein when a turn-on signal is applied to a gate electrode of the connection thin-film transistor, a turn-off signal is applied to a gate electrode of the signal application thin-film transistor.

12. A display apparatus comprising:
a first substrate having a first display area;
first pads disposed on the first substrate along a first edge of the first substrate;
first data lines crossing the first display area and extending to the first pads;
a second substrate having a second display area;
second pads disposed on the second substrate along a second edge of the second substrate;
a connection film having one end electrically connected to the first pads and another end electrically connected to the second pads;
connection thin-film transistors, each having one end electrically connected to a corresponding one of the first data lines and another end electrically connected to a corresponding one of the first pads; and
signal application thin-film transistors, each having one end electrically connected to a ground line and another end electrically connected to a corresponding one of the first pads.

13. The display apparatus of claim 12, wherein gate electrodes of the connection thin-film transistors are electrically connected to each other.

14. The display apparatus of claim 13, wherein the gate electrodes of the connection thin-film transistors are integrally formed as a single body.

15. The display apparatus of claim 12, wherein gate electrodes of the signal application thin-film transistors are electrically connected to each other.

16. The display apparatus of claim 15, wherein the gate electrodes of the signal application thin-film transistors are integrally formed as a single body.

17. The display apparatus of claim 12, wherein when a turn-off signal is applied to gate electrodes of the connection thin-film transistors, a turn-on signal is applied to gate electrodes of the signal application thin-film transistors.

18. The display apparatus of claim 12, wherein when a turn-on signal is applied to gate electrodes of the connection thin-film transistors, a turn-off signal is applied to gate electrodes of the signal application thin-film transistors.

19. The display apparatus of claim 12, further comprising connection lines arranged in the connection film, wherein each of the connection lines electrically connect a corresponding one of the first pads to a corresponding one of the second pads.

20. The display apparatus of claim 12, further comprising second data lines crossing the second display area and extending to the second pads, wherein each of the second data lines is electrically connected to a corresponding one of the second pads.
